(19) United States
(12) Patent Application Publication
(10) Pub. No.: US 2017/0338429 A1
(43) Pub. Date: Nov. 23, 2017

(54) DISPLAY DEVICE

(71) Applicant: Japan Display Inc., Tokyo (JP)

(72) Inventor: Kazufumi WATABE, Tokyo (JP)

(21) Appl. No.: 15/596,052

(22) Filed: May 16, 2017

(30) Foreign Application Priority Data
May 23, 2016 (JP) 2016-102472

(51) Int. Cl. H01L 51/00; H01L 51/52; H01L 51/56; H01L 27/32; H01L 27/12

(52) U.S. Cl. CPC H01L 51/0097; H01L 51/5271; H01L 51/5253; H01L 51/56; H01L 27/1218; H01L 27/3244; H01L 2251/303

(57) ABSTRACT

The invention provides a reliable organic EL display device with improved moisture barrier characteristics. An organic EL display device includes: an organic EL layer as a light-emitting layer formed on a resin substrate; and a barrier layer formed between the organic EL layer and the resin substrate, the barrier layer including an undercoat layer and AlOx layer. The undercoat layer is formed closer to the resin substrate than the AlOx layer.

### CLAIM OF PRIORITY

The present application claims priority from Japanese Patent Application JP 2016-102472 filed on May 23, 2016, the content of which is hereby incorporated by reference into this application.

### BACKGROUND OF THE INVENTION

### 1. Field of the Invention

The present invention relates to display devices and particularly to a flexible display device with a bendable substrate.

### 2. Description of the Related Art

Organic electroluminescent (EL) display devices and liquid crystal display devices can be made thin enough to be bent flexibly. In such a case, the substrate on which various elements are to be formed is made of thin glass or thin resin. In terms of reducing device thickness, organic EL display devices have an advantage over liquid crystal display devices because the former do not involve the use of a backlight. The same is true of reflective liquid crystal display devices.

The organic EL materials that constitute the light-emitting layer of an organic EL display device may decompose in the presence of moisture, and their performance may be degraded. Thus, in order to ensure long durability, the organic EL layer needs to be protected from moisture. As a moisture barrier, a laminated layer of silicon oxide (SiO) and silicon nitride (SiN) is now being used.

Aluminum oxide (AlOx) films are also being used in the fields of optics and electronics because they are transparent. According to Journal of Vacuum Science and Technology, A 12 (2), 321-322, March/April 1994, the refractive index of Al₂O₃ (included in the category of AlOx) becomes larger as its density gets larger.

### SUMMARY OF THE INVENTION

SiO (the term SiO used herein refers to a compound whose basic structure is SiO₂, but the term SiO generally refers to compounds that deviate from the stoichiometric composition) and SiN (the term SiN used herein refers to a compound whose basic structure is Si₃N₄, but the term SiN generally refers to compounds that deviate from the stoichiometric composition), which have been used as barriers, may not have sufficient barrier capabilities to protect the organic EL layer. The quality of such barrier films also has a great influence on their barrier performance

The present inventors have found that, in the case of AlOx barrier films as well (the term AlOx used herein refers to a compound whose basic structure is Al₂O₃, but the term AlOx generally refers to compounds that deviates from the stoichiometric composition x=1.5), the quality of the AlOx films has a great influence on their barrier performance.

An object of the invention is to provide an organic EL display device that has excellent barrier capabilities to protect its organic EL layer, thereby achieving excellent reliability and durability.

### MEANS FOR SOLVING THE PROBLEMS

The invention is designed to achieve the above object and can be implemented as the following means.

(1) An organic EL display device including: an organic EL layer as a light-emitting layer formed on a resin substrate; and a barrier layer formed between the organic EL layer and the resin substrate, the barrier layer including an undercoat layer and AlOx layer, wherein the undercoat layer is formed closer to the resin substrate than the AlOx layer.

(2) An organic EL display device including: an organic EL layer as a white-light-emitting layer formed on a first resin substrate; a first barrier layer formed on the first resin substrate, the first barrier layer including a first undercoat layer and first AlOx layer, the first undercoat layer being formed closer to the first resin substrate than the first AlOx layer; a second resin substrate covering the organic EL layer; a second barrier layer formed between the second resin substrate and the organic EL layer, the second barrier layer including a second undercoat layer and second AlOx layer, the second undercoat layer being formed closer to the second resin substrate than the second AlOx layer; and a color filter formed between the second barrier layer and the organic EL layer.

(3) An organic EL display device including: an organic EL layer as a light-emitting layer formed on a resin substrate, the organic EL layer being sandwiched between an upper electrode and a lower electrode, the lower electrode not being in contact with a metal layer constituting a reflective film, a barrier layer formed between the lower electrode and the resin substrate, the barrier layer including the metal layer and AlOx layer, the metal layer being formed closer to the resin substrate than the AlOx layer, the metal layer constituting the reflective film.

### BRIEF DESCRIPTION OF THE DRAWINGS

FIG. 1 is a plan view of a flexible display device;

FIG. 2 is a cross section taken along line A-A of FIG. 1;

FIG. 3 is a cross section of the barrier layer of a conventional display device;

FIG. 4 is a cross section of a barrier layer according to the invention;

FIGS. 5A to 5D are diagrams illustrating the process for forming the barrier layer of the invention;

FIG. 6 is a schematic cross section of a sputtering device used to form the barrier layer of the invention;

FIG. 7 is a graph illustrating the relation between vapor pressure and the refractive index of AlOx at the time of forming the AlOx layer;

FIG. 8 is a cross section of a barrier layer according to Embodiment 2 of the invention;

FIG. 9 is a table illustrating the advantageous effects achieved by the invention;

FIG. 10 is a diagram of procedure illustrating how to measure water vapor transmission rates;

FIG. 11 is a detailed cross section of the display area of an organic EL display device;

FIG. 12 is a cross section illustrating the structure of an organic EL display device according to Embodiment 3 of the invention;

FIG. 13 is a cross section illustrating the structure of an organic EL display device according to Embodiment 4 of the invention;

FIG. 14 is a cross section of the barrier layer of Embodiment 4;

FIG. 15 is a cross section illustrating another example of the barrier layer of Embodiment 4;

FIG. 16 is a cross section illustrating the structure of an organic EL display device according to Embodiment 5 of the invention;

FIGS. 17A to 17D are diagrams illustrating the process for forming the barrier layer of Embodiment 5; and

FIGS. 18A to 18D are diagrams illustrating the process for forming another barrier layer according to Embodiment 5.

### DESCRIPTION OF THE PREFERRED EMBODIMENTS

Embodiments of the present invention will now be described in detail.

### Embodiment 1

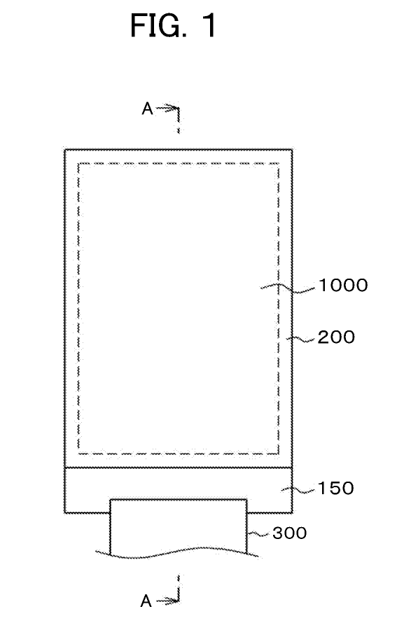

FIG. 1 is a plan view of an organic EL display device to which the invention is applied. The organic EL display device of the invention can be bent flexibly. As illustrated in FIG. 1, the organic EL display device includes a display area 1000 and a terminal section 150. An anti-reflective polarizing plate 200 is glued in the display area 1000. A flexible wiring substrate 300 is connected to the terminal section 150 to supply electric power and signals to the organic EL display device.

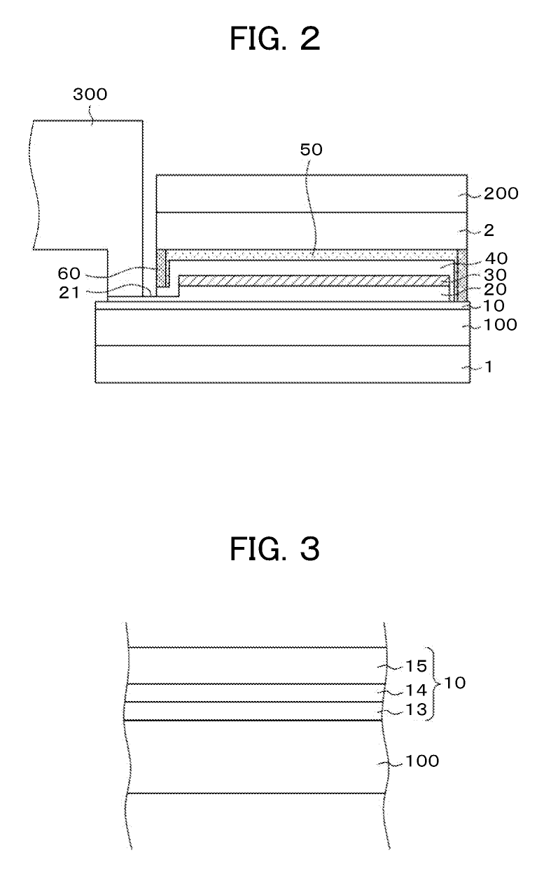

FIG. 2 is a cross section taken along line A-A of FIG. 1. As illustrated, the display area and the terminal section are formed on a polyimide substrate 100. The polyimide substrate 100 is 10 to 20 μm thick and can be bent flexibly. As will be described later, the polyimide substrate 100 is formed by applying a material on a glass substrate and then baking it. Since the polyimide substrate 100 is thin and unstable in terms of shape, a first protective film 1 is glued to its rear surface. The first protective film 1 is formed of polyethylene terephthalate (PET) or acrylic resin and has a thickness of about 0.1 to 0.2 mm

As illustrated in FIG. 2, a first barrier layer 10 is formed on the polyimide substrate 100. The first barrier layer 10 is used to protect an organic EL layer 30 from moisture and the like. Formed on the first barrier layer 10 is an array layer 20 that includes thin film transistors (TFTs) and the like. The array layer 20 is used to control the light emittance from the organic EL layer of each pixel. Formed on the array layer 20 is the organic EL layer 30 that include a light emitting layer.

A second barrier layer 40, made of SiN or the like, is formed in such a way as to cover the organic EL layer 30. Similar to the first barrier layer 10, the second barrier layer 40 is also used to protect the organic EL layer 30 from external moisture and the like. Over the second barrier layer 40 is an epoxy-based adhesive 50, which is used for the adhesion of a second protective film 2. The adhesive 50 is a UV-curable resin and in the form of liquid before being cured. To prevent the adhesive 50 from flowing outward, a dam 60 is formed at the peripheral region of the display area. The dam 60 is formed of a quick-drying, epoxy-based resin.

The second protective film 2 provides mechanical protection for the organic EL layer 30. The second protective film 2 is formed of PET or acrylic resin and has a thickness of about 0.1 mm. The polarizing plate 200 is glued to the second protective film 2 so as to cover it. Organic EL display devices of the top emission type reflect external light because they include reflective electrodes. Thus, the polarizing plate 200 is provided to prevent reflection of external light.

As further illustrated in FIG. 2, metal-made lead wires 21, which constitute part of the array layer 20, extend from the display area to the terminal section. The second barrier layer 40 extends up to part of the terminal section so as to cover part of the lead wires 21. The flexible wiring substrate 300 is connected to the terminal section to supply electric power and signals to the organic EL display device. Since the display area of the invention is flexible and has a small thickness, the flexible wiring substrate 300 is shown relatively thick in FIG. 2.

A feature of the invention lies in the structure of the first barrier layer 10. Since the organic EL layer is easily affected by moisture, it is necessary to block the moisture infiltration from the outside. On the other hand, as illustrated in FIG. 2, the organic EL display device of the invention uses a polyimide substrate as the substrate 100. The polyimide substrate 100 tends to contain moisture. The moisture contained in the polyimide substrate 100 is released during the operation of the organic EL display device, deteriorating the organic EL layer. Therefore, the first barrier layer 10 needs to have the function of blocking external moisture and the moisture released from the polyimide substrate 100.

FIG. 3 illustrates an example in which the first barrier layer 10 is formed of SiO and SiN. In FIG. 3, a first layer 13 on the polyimide substrate 100 is formed of SiO and 50 nm thick. A second layer 14 is formed of SiN and 50 nm thick. A third layer 15 is formed of SiO and 300 nm thick. This layer structure formed of SiO and SiN, however, does not provide sufficient moisture protection for the organic EL layer.

In the invention, therefore, AlOx is also used for the first barrier layer 10. However, as will be described later in detail, the present inventors have found that, if AlOx layer is formed directly on the polyimide substrate 100, the first barrier layer 10 cannot have sufficient moisture blocking functions. Specifically, if AlOx layer is formed directly on the polyimide substrate 100, the moisture released from the polyimide substrate 100 deteriorates the film quality of the AlOx layer, so the AlOx cannot have sufficient moisture blocking characteristics. Thus, in the present invention, an undercoat layer is also formed between the AlOx layer and the polyimide substrate 100.

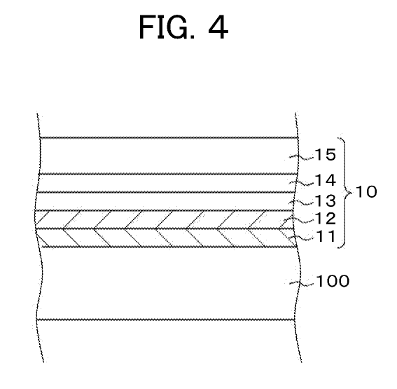

FIG. 4 is a cross section illustrating the structure of the first barrier layer 10 of the invention. As illustrated in FIG. 4, a metal layer 11, made of Al or the like, is formed on the polyimide substrate 100. An AlOx layer 12 is then formed on the metal layer 11. Formed on the AlOx layer 12 are the SiO layer 13, the SiN layer 14, and the SiO layer 15, as is similar to FIG. 3. With such a layer structure, the metal-made undercoat layer 11, provided as an undercoat layer, can absorb the moisture released from the polyimide substrate 100 at the time of forming the AlOx layer 12. Thus, it is possible to prevent the film quality of the AlOx layer 12, which is formed by sputtering, from being deteriorated due to the moisture.

The metal layer 11 can also be formed of a material other than Al that easily reacts with moisture, such as Ti. The metal layer 11 only needs to be 10 to 20 nm thick in order to absorb the moisture released from the polyimide substrate 100 at the time of forming the AlOx layer 12. The thicker the metal layer 11, the higher moisture blocking effect it will have. Thus, the metal layer 11 can be made thicker if fabricating conditions permit. The metal layer 11 is formed by sputtering.

Because the AlOx layer 12 is dense and has a high moisture blocking effect, it only needs to be 50 to 80 nm thick. The AlOx layer 12 is also formed by sputtering. The SiO layer 13, SiN layer 14, and SiO layer 15 above the AlOx layer 12 are formed by chemical vapor deposition (CVD).

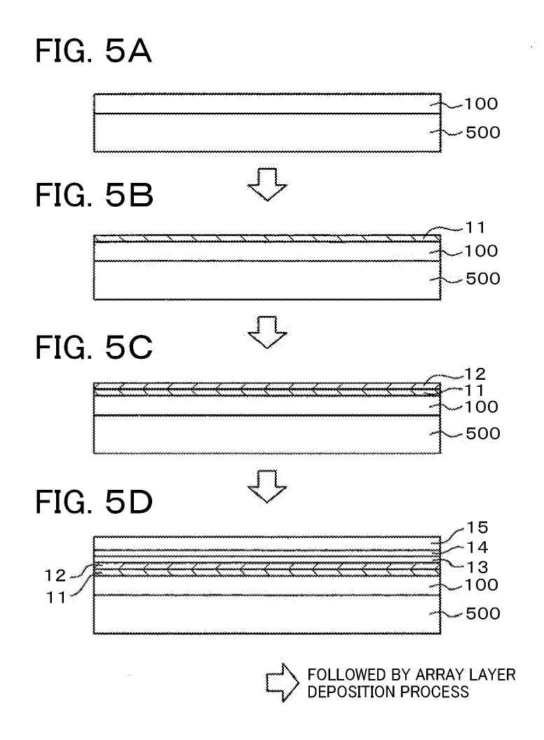

FIGS. 5A to 5D are process flow diagrams according to the invention for forming the first barrier layer 10 on the polyimide substrate 100. A process FIG. 5A illustrates a state in which the polyimide substrate 100 is formed on a glass substrate 500. The glass substrate 500 illustrated in FIG. 5A is used to put the polyimide substrate 100 through the production line for forming the organic EL display device and has a thickness of about 0.5 mm. After the completion of the organic EL display device, the glass substrate 500 is removed and the first protective film 1 of FIG. 2 is replaced by the polyimide substrate 100. The glass substrate 500 is a mother substrate on which many other organic EL cells are formed. In the process FIG. 5A, a polyimide material is applied onto the glass substrate 500 with the use of a slit coater or the like. The glass substrate 500 is then pre-baked, followed by secondary baking at about 500 degrees Celsius. Thereafter, as illustrated in a process (of FIG. 5B, Al is deposited by DC, AC, or RF sputtering as the undercoat layer 11 having a thickness of, for example, 20 to 30 nm. The sputtering target is Al, and the sputtering gas is Ar. Thereafter, as illustrated in a process of FIG. 5C, the AlOx layer 12 is formed as a barrier layer by DC, AC, or RF sputtering. The AlOx layer 12 has a thickness of about 30 to 80 nm. The sputtering target for forming the AlOx layer 12 is Al, and the AlOx layer 12 is formed by reactive sputtering in which Ar and O₂ are used. The resultant AlOx layer 12 is a dense film having excellent moisture blocking capabilities since the moisture released form the polyimide substrate 100 is blocked by the undercoat layer 11 made of Al. Thereafter, as illustrated in a process FIG. 5D, the tree layers composed of the SiO layer 13, the SiN layer 14, and the SiO layer 15 are formed on the AlOx layer 12 by CVD.

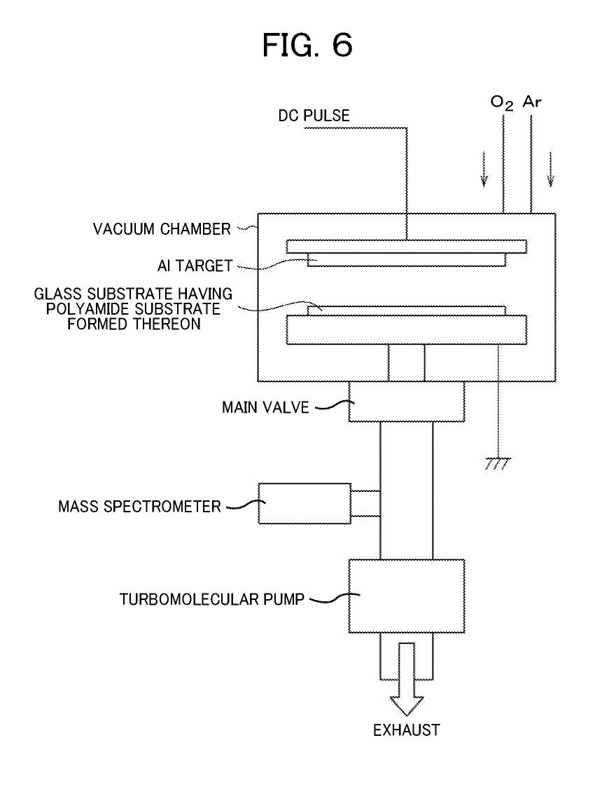

FIG. 6 is a schematic cross section of a sputtering device for depositing the Al and AlOx. As illustrated in FIG. 6, an Al target and the glass substrate 500 on which the polyimide substrate 100 is formed are disposed within the vacuum chamber such that they face each other. Also, a turbomolecular pump, used as a vacuum pump, is connected to the vacuum chamber via a main valve so that a vacuum is created in the vacuum chamber. A cryopump is not usually used because O₂ is used at the time of film formation. Thus, the vapor pressure within the vacuum chamber will decrease relatively less. A mass spectrometer is connected to the exhaust duct.

For sputtering, a DC pulse is supplied to the Al target. When the Al is deposited, only Ar is supplied into the vacuum chamber. In contrast, when the AlOx is deposited, Ar and O₂ are supplied into the vacuum chamber, and reactive sputtering is performed to deposit the AlOx. Thus, the Al, or the undercoat layer, and the AlOx, or the barrier layer, can be formed successively.

Table 1 below shows an example of sputtering conditions for depositing the Al.

TABLE 1
Conditions for Al deposition

| | |
|---|---|
| Gas flowrate | Argon supplied at 100 sccm |
| Input power | 11.2 kW (2.8 kW × 4 machines) |
| | Frequency of driving pulse: 20 kHz |
| Ultimate pressure | 5 × 10⁻⁵ Pa |
| Deposition pressure | 0.3 Pa |
| Deposition temperature | 60 degrees Celsius |
| Deposition rate | 380 nm/min (6.3 nm/sec) |

Table 2 below shows an example of sputtering conditions for depositing the AlOx.

TABLE 2
Conditions for AlOx deposition

| | |
|---|---|
| Substrate size | 730 mm × 920 mm (0.5 mm thick) |
| Gas flowrate | Oxygen: 300 sccm |
| | Argon: 100 sccm |
| Target used | 4 pieces |
| Input power | 20 kW (5 kW × 4 machines) |
| | Frequency of driving pulse: 20 kHz |
| Ultimate pressure | 5 × 10⁻⁵ Pa |
| Deposition pressure | 0.5 Pa |
| Deposition temperature | 60 degrees Celsius |
| Deposition rate | 2 nm/min |

The AlOx barrier layer of the invention is dense and has excellent moisture blocking capabilities so as to be immune to the influence of moisture during sputtering. There is a correlation between the density and refractive index of the AlOx: the higher the refractive index, the denser the AlOx film. Also, as the vapor pressure during sputtering becomes smaller, an AlOx film with a higher refractive index, or a denser AlOx film can be formed.

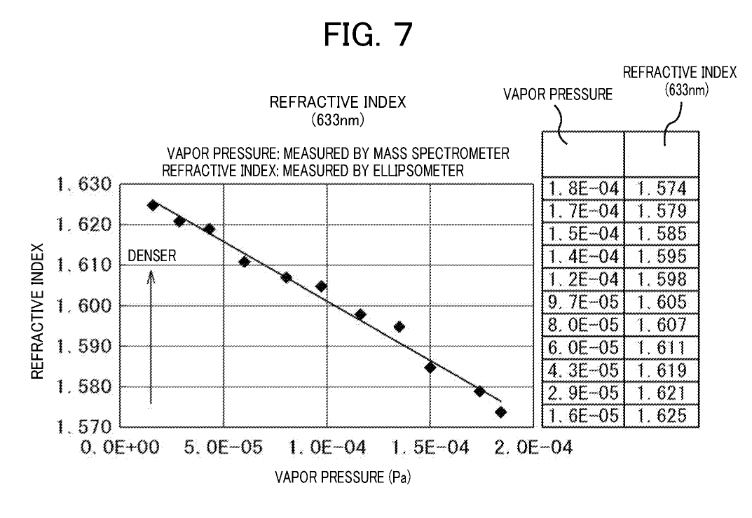

FIG. 7 is a graph illustrating the above relation between the vapor pressure and the refractive index. To obtain the data of FIG. 7, a glass substrate was used for measuring the refractive index of the AlOx itself. In FIG. 7, the horizontal axis represents the vapor pressure during sputtering on a logarithmic scale while the vertical axis represents the refractive index of the AlOx with respect to light of a 633 nm wavelength. As illustrated in FIG. 7, as the vapor pressure becomes smaller, the refractive index becomes larger, or the AlOx film becomes denser. This means that deviation from the stoichiometric composition of the AlOx (x=1.5) is controlled.

If the AlOx is formed directly on the polyimide substrate 100 on the glass substrate 500 as illustrated in FIG. 6, moisture is released from the polyimide substrate 100, which in turn reduces the density of the AlOx film formed on the polyimide substrate 100. Thus, the Al is deposited as the undercoat layer 11 before the formation of the AlOx layer 12 so that the density of the AlOx layer 12 can be increased.

Another advantage of using the metal layer is that static electricity is prevented from accumulating in the vacuum chamber of the sputtering device because an electrically conductive layer is formed periodically in the vacuum chamber. Since static electricity may damage electronic elements, the conventional approach adopted when forming only the AlOx film is to form an Al film on a dummy substrate after the film deposition process, thereby periodically forming an electrically conductive layer in the vacuum chamber to prevent the occurrence of static electricity. According to the invention, this process of forming an electrically conductive film in the vacuum chamber is not necessary, and part of the maintenance for the sputtering device can be skipped.

### Embodiment 2

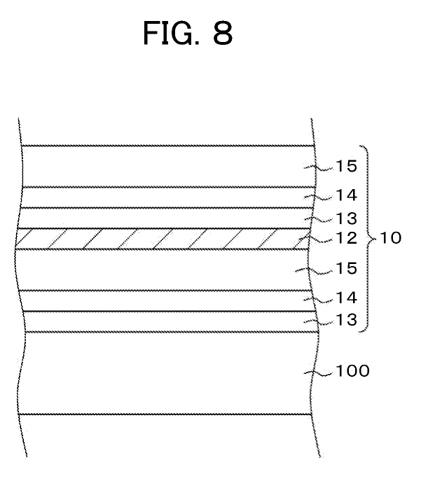

A feature of the invention is that when the AlOx is formed, the influence of moisture is reduced, thereby forming a dense AlOx film having high moisture blocking capabilities. In order to reduce the vapor pressure during the formation of the AlOx, the metal layer can instead be formed of SiO and SiN layer. FIG. 8 illustrates an example in which a laminated layer of an SiO film and an SiN film is used as the undercoat layer 11 of the first barrier layer 10 of FIG. 2. The laminated layer is, for example, an SiO/SiN/SiO layer, the thickness of each of which is 50 nm, 50 nm, and 300 nm. Such an undercoat layer can also be formed by CVD. Another laminated layer of an SiO/SiN/SiO (50, 50, 300 nm thick, respectively) layer is also formed on the AlOx layer 12, as is similar to the undercoat layer.

In the case of using the undercoat layer of FIG. 8 as well, the moisture infiltration from the polyimide substrate 100 can be prevented while the AlOx layer 12 is deposited by sputtering. As a result, a dense AlOx layer 12 can be obtained. Although FIG. 8 illustrates an example in which a three-layered structure of undercoat layer composed of SiO and SiN is used, the invention is not limited thereto. Alternatively, an undercoat layer of SiN or SiO alone can also provide sufficient moisture protection.

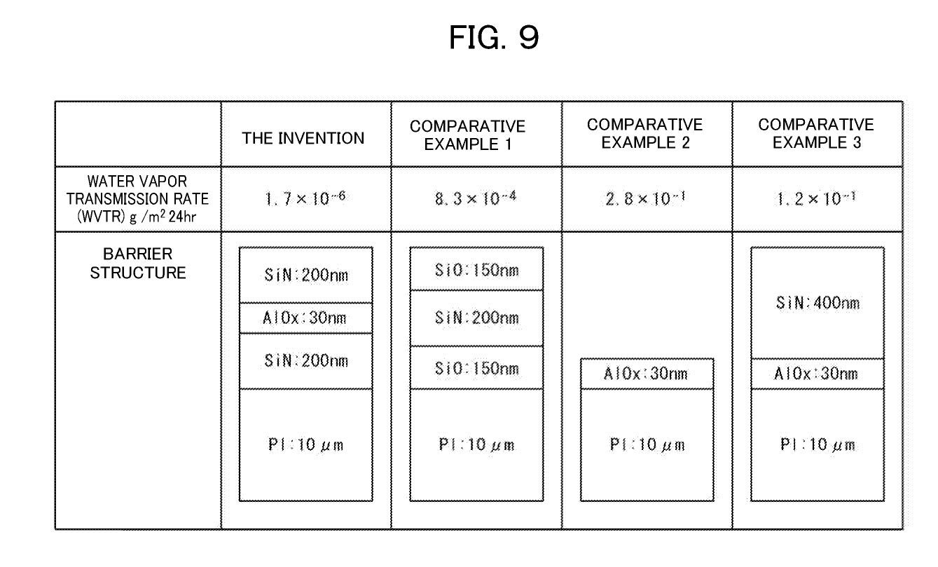

FIG. 9 is a table in which a barrier layer according to the invention is compared with other barrier layers in terms of water vapor blocking effects. The barrier layer of the invention includes an SiN undercoat layer (200 nm thick) on the polyimide substrate and an AlOx barrier layer (30 nm thick) on the undercoat layer. The barrier layer of Comparative Example 1 is made up of a laminated layer of an SiO/SiN/SiO (150, 200, 150 nm thick, respectively) layer on the polyimide substrate. The barrier layer of Comparative Example 2 is made up of an AlOx layer (30 nm thick) alone on the polyimide substrate. The barrier layer of Comparative Example 3 is made up of an AlOx layer (30 nm thick) formed directly on the polyimide substrate and an SiN layer (400 nm thick) on the AlOx layer.

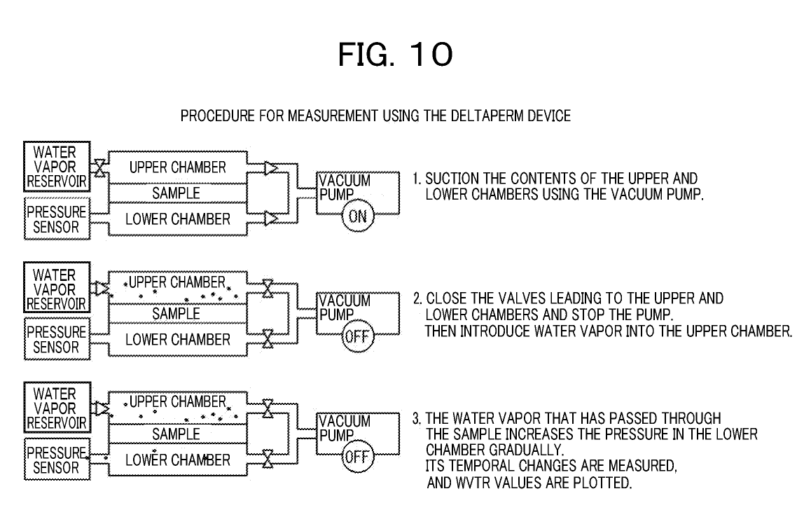

FIG. 9 shows the results of comparison of the barrier layers between the invention and Comparative Examples 1 to 3 in terms of water vapor transmission rate (WVTR). FIG. 10 is a diagram of procedure illustrating how we measured the WVTRs using a device called DELTAPERM. As illustrated in FIG. 10, the upper chamber of the device was first filled with gas containing water vapor, and the amounts of water vapor passing through a sample for a given amount of time were then measured. The sample of FIG. 10 corresponds to the barrier layers of FIG. 9.

Referring back to FIG. 9, the water vapor transmission rate (WVTR) of each barrier layer was obtained by measuring in g/m² the amount of water vapor passing through each barrier layer for 24 hours. The WVTR of Comparative Example 1 in which SiO and SiN are used as a barrier layer is 8.3×10⁻⁴ while that of the invention is reduced to 1.7×10⁻⁶, meaning the invention is far more effective. In other words, the invention allows formation of a denser AlOx film.

The WVTR of Comparative Example 2 in which only AlOx film (30 nm thick) is used as a barrier is 2.8×10⁻¹, meaning the barrier layer has a very small effect. The reason is that, during the deposition of the AlOx, the water vapor released from the polyimide substrate deteriorates the film quality of the AlOx, resulting in an AlOx film with an insufficient barrier effect.

Comparative Example 3 is the case where an AlOx layer (30 nm thick) is formed directly on the polyimide substrate and an SiN layer (400 nm thick) is formed on the AlOx layer. The WVTR of Comparative Example 3 is only slightly better than that of Comparative Example 2, thus, Comparative Example 3 does not provide a sufficient barrier effect, either.

As can be seen, when the polyimide substrate acts as an undercoat layer, the AlOx layer formed on the polyimide substrate by sputtering cannot have a sufficient barrier effect. In other words, only when an undercoat layer is present between the AlOx layer and the polyimide substrate can a sufficient moisture blocking effect be obtained. As shown in FIG. 9, the barrier layer of the invention has a far greater moisture barrier effect than those of Comparative Examples 1 to 3.

### Embodiment 3

An organic EL display device of the top emission type requires a reflective film to direct the light emitted from its organic EL layer, which includes a light emitting layer, toward its screen side. This reflective film, made of Al or the like, is formed underneath the lower electrode of the organic EL layer. According to the invention, when Al is used as the undercoat layer for AlOx, this undercoat layer can also be used as a reflective film, which makes the typical reflective film unnecessary.

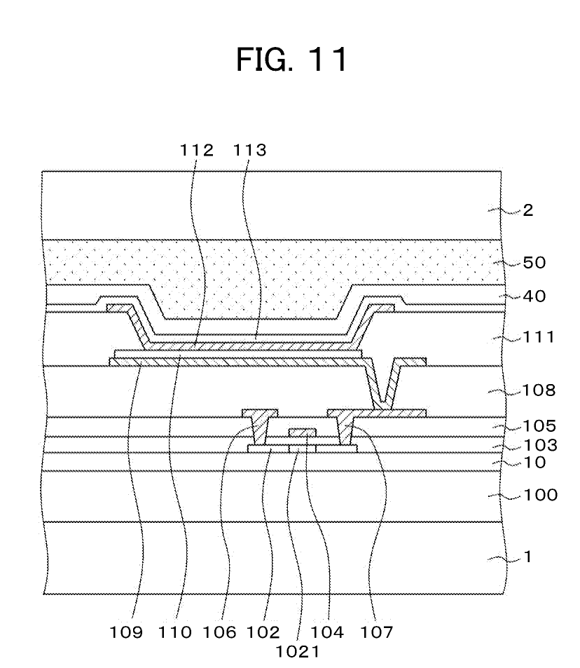

FIG. 11 is a cross section illustrating the structure of a typical organic EL display device of the top emission type. As illustrated in FIG. 11, the first barrier layer 10 of Embodiment 1 is formed on the polyimide substrate 100, which is 10 to 20 μm thick. A semiconductor layer 102 is formed on the first barrier layer 10. The semiconductor layer 102 is formed by depositing amorphous silicon (a-Si) by CVD and then converting it into Poly-Si with the use of an excimer laser.

A gate insulating film 103 is formed to cover the semiconductor layer 102. The gate insulating film 103 is formed of SiO by CVD in which tetraethyl orthosilicate (TEOS) is used. A gate electrode 104 is formed on the gate insulating film 103. Ion implantation is then used to convert the section of the semiconductor layer 102 that does not overlap the gate electrode 104 into a conductive layer. The other section of the semiconductor layer 102 that overlaps the gate electrode 104 serves as a channel section 1021.

An inter-layer insulating film 105 is formed to cover the gate electrode 104. The inter-layer insulating film 105 is formed of SiN by CVD. Through-holes are then formed in the inter-layer insulating film 105 and the gate insulating film 103. Provided in the through-holes are a drain electrode 106 and a source electrode 107 for connection therebetween. As illustrated in FIG. 11, an organic passivation film 108 is then formed to cover the drain electrode 106, the source electrode 107, and the inter-layer insulating film 105. The organic passivation film 108 is formed thick (e.g., 2 to 3 μm) because it needs to act also as a planarizing film. The organic passivation film 108 is formed of, for example, acrylic resin.

A reflective electrode 109 is formed on the organic passivation film 108, and a lower electrode 110 is formed on the reflective electrode 109. The lower electrode 110, which serves as an anode, is formed of a transparent conductive film such as ITO. The reflective electrode 109 is formed of an Al alloy with a high reflectance. The reflective electrode 109 is connected to the source electrode 107 of the TFT via a through-hole formed in the organic passivation film 108.

An acrylic-made bank 111 is formed around the lower electrode 110. The purpose of the bank 111 is to prevent conductivity failure of next-formed layers that are an organic EL layer 112 including a light emitting layer and an upper electrode 113, the conductivity failure resulting from stepped surfaces. The bank 111 is formed by applying a transparent resin, such as an acrylic resin, onto the entire surface and then forming a hole in the section of the resin that overlaps the lower electrode 110 so that light can be extracted from the organic EL layer 112.

As illustrated in FIG. 11, the organic EL layer 112 is formed on the lower electrode 110. The organic EL layer 112 includes, for example, an electron injection layer, an electron transport layer, a light emitting layer, a hole transport layer, and a hole injection layer. It should be noted that the conception of the organic EL layer 30 of FIG. 2 is such that the organic EL layer 30 includes the organic EL layer 112, the upper electrode, and the lower electrode. Formed over the organic EL layer 112 is the upper electrode 113, which acts as a cathode. The upper electrode 113 can be formed of a transparent conductive film such as indium zinc oxide (IZO) and indium tin oxide (ITO) or of a metal thin film such as a silver film.

To prevent the moisture infiltration from the side of the upper electrode 113, the second barrier layer 40 is formed on the upper electrode 113. The second barrier layer 40 is formed of SiN by CVD. Because the organic EL layer 112 is easily affected by heat, the CVD used to form the second barrier layer 40 is conducted at a lower temperature, for example, 100 degrees Celsius. The second protective film 2 is glued to the second barrier layer 40 via an adhesive 50.

The above reflective electrode 109 is necessary for a typical top-emission organic EL display device. The reflective electrode 109, formed of an Al alloy, is formed by sputtering, followed by photolithographic patterning.

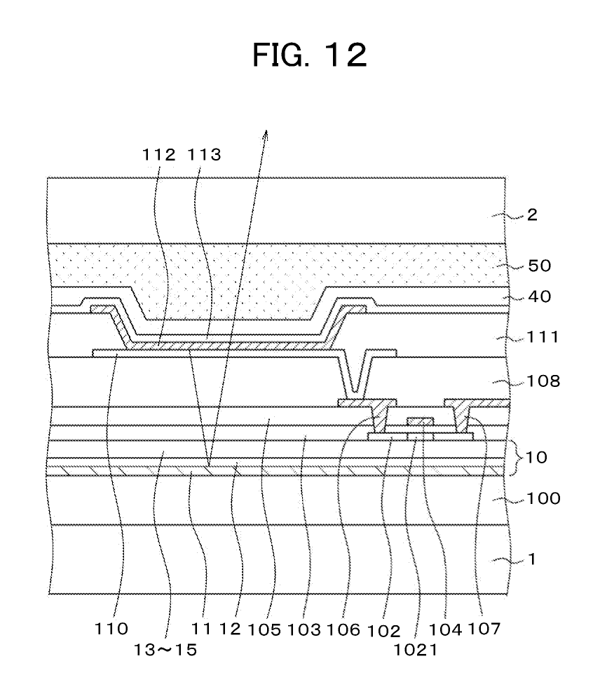

FIG. 12 is a cross section of an organic EL display device according to Embodiment 3. FIG. 12 is the same as FIG. 11 except that the first barrier layer 10 is structurally different and that the reflective electrode (reflective film) 109 that is in contact with the lower electrode 110 is not present in FIG. 12. Since the reflective film 109 that is in contact with the lower electrode 110 is not present in FIG. 12, the lower electrode 110 is electrically connected to the drain electrode 106 via a though-hole.

As illustrated in FIG. 12, the undercoat layer 11 made of Al is formed on the polyimide substrate 100, and the AlOx layer 12 is formed on the undercoat layer 11. Formed on the undercoat layer 11 is a laminated layer of an SiO/SiN/SiO layer, as denoted by the reference numerals 13 to 15. Although there is no reflective film that is in contact with the lower electrode 111 of the organic EL layer 112, the light radiated from the organic EL layer 112 can be reflected by the undercoat layer 11 made of Al. Thus, in the present embodiment, the undercoat layer 11 made of Al needs to be thick enough to have a sufficient reflectance. This can be achieved easily because the sputtering rate of the Al is high.

Since the undercoat layer 11 made of Al is used as a reflective film, there is no TFT between the organic EL layer 112 and the undercoat layer 11, as illustrated in FIG. 12. This is to eliminate the influence on the characteristics of the photoelectric effect on the TFT.

As described above, in Embodiment 3, there is no need to form a reflective film that is in contact with the lower electrode. A reflective film is formed by a process including sputtering and photolithography, and the latter can be skipped when the Al layer as the undercoat layer 11 is used as a reflective film as in the present embodiment. As a result, manufacturing cost can be reduced.

### Embodiment 4

In Embodiments 1 and 2, an undercoat layer and an AlOx layer are formed as the first barrier layer between the organic EL layer and the polyimide substrate, so that the moisture barrier effect for the organic EL layer can be increased. On the other hand, moisture infiltrates the organic EL layer not only from the lower layer side but also from the upper layer side. Conventionally, the second barrier layer (SiN layer) disposed on the upper electrode is provided to block the moisture entering from the upper layer side, but this does not provide a sufficient blocking effect.

The SiN layer that constitutes the second barrier layer is formed by low-temperature CVD at about 100 degrees Celsius so as not to deteriorate the organic EL layer. As a result, the SiN film cannot have sufficient strength and density, nor does it provide a sufficient moisture blocking effect.

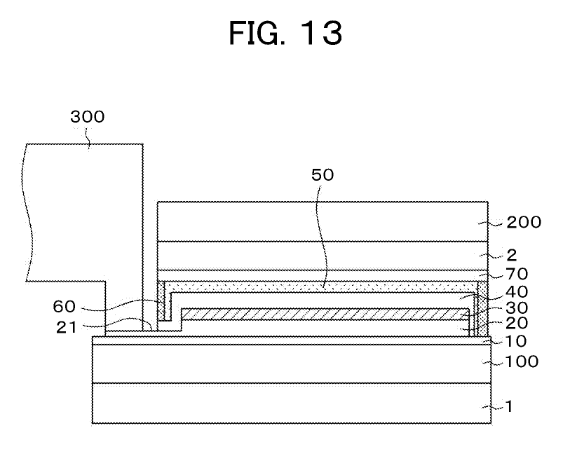

Embodiment 4 is designed to ensure more reliable prevention of the moisture infiltration from the air. As illustrated in FIG. 13, a third barrier layer 70 is formed on the second protective film 2. FIG. 13 is a cross section of an organic EL display device according to Embodiment 4 and the same as FIG. 2 except for the presence of the third barrier layer 70 on the second protective film 2.

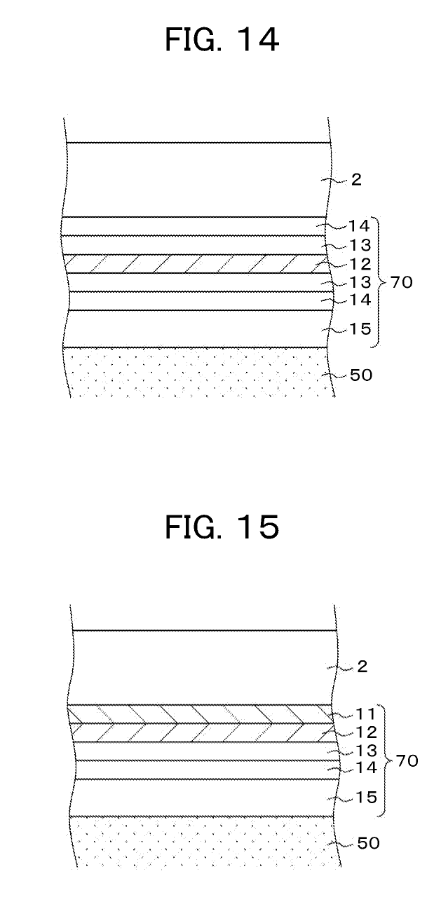

In FIG. 13, the third barrier layer 70 is formed on the second protective film 2. FIG. 14 is a cross section illustrating an example of the structure of the third barrier layer 70. As illustrated in FIG. 14, a laminated layer of the SiN layer 14 and SiO layer 13 is formed as an undercoat layer on the second protective film 2. The SiN and SiO can instead be such a three-layered structure as illustrated in FIG. 5 or a single layer structure of SiN or SiO.

As further illustrated in FIG. 14, the AlOx layer 12, which is 30 to 80 nm thick, is formed on the laminated SiN/SiO layer. On the AlOx layer 12 is a three-layered structure of SiO/SiN/SiO. Because all of the SiN, SiO, and AlOx are transparent, they do not affect the organic EL display device of the top emission type.

FIG. 15 illustrates another example of the third barrier layer 70 of Embodiment 4. FIG. 15 differs from FIG. 14 in that, in the former, the metal layer 11 made of Al or the like is used as the undercoat layer between the AlOx layer 12 and the second protective film 2. The rest is the same. The metal layer 11 can have the required transmittance if it is thin enough. Also, a thin metal layer satisfactorily serves the role of the undercoat layer. Thus, in an organic EL display device of the top emission type such as the one in FIG. 13, a thin metal layer can be used as the undercoat layer.

Embodiment 4 ensures reliable protection of the organic EL layer from moisture entering from the upper layer side and the upper layer side, which results in a highly reliable organic EL display device.

### Embodiment 5

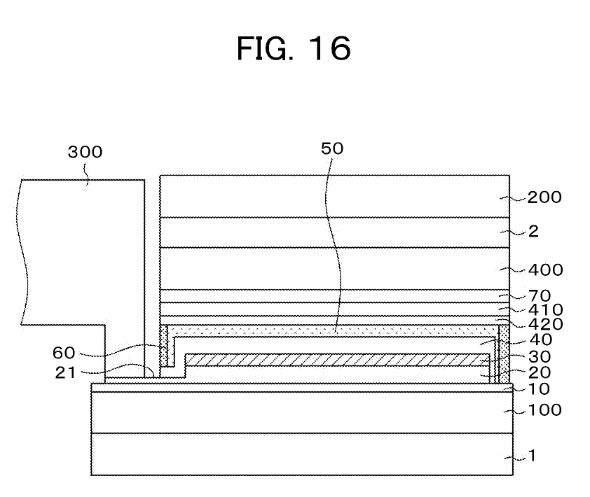

FIG. 16 is a cross section according to Embodiment 5. In this embodiment, an organic EL layer that emits white light is used. Thus, a color filter needs to be present on the side of the second protective film 2. FIG. 16 is the same as FIG. 2 in terms of the structure below the second barrier layer 40. In the present embodiment, the structure above the second barrier layer 40 is different from that in FIG. 2.

As illustrated in FIG. 16, the third barrier layer 70 is formed on a second polyimide substrate 400. While, in FIG. 13 related to Embodiment 4, the third barrier layer 70 is formed directly on the second protective film 2, it is formed on the second polyimide substrate 400 in FIG. 16. The structure of the third barrier layer 70 will be described later. A color filter 410 is formed on the third barrier layer 70, and an overcoat film 420 is formed on the color filter 410. The reason the overcoat film 420 is formed on the color filter 410 is to prevent the pigments of the color filter 410 from exuding into other layers.

To fabricate the above structure, the polyimide substrate 400, which is 10 to 20 μm thick, is first formed on a glass substrate that is subjected to various manufacturing processes. This glass substrate is later removed from the polyimide substrate 400 by laser abrasion or the like and replaced by the second protective film 2. The third barrier layer 70 is formed on the polyimide substrate 400, followed by the formation of the color filter 410 and the overcoat film 420 on the third barrier layer 70. Thereafter, the resultant structure is glued to the other half, that is, the first polyimide substrate 100 on which the organic EL layer 30, a dam 60, an adhesive 50, and so forth have been formed. After the adhesion, the glass substrate is removed from the second polyimide substrate 400 by laser abrasion or the like and replaced by the second protective film 2.

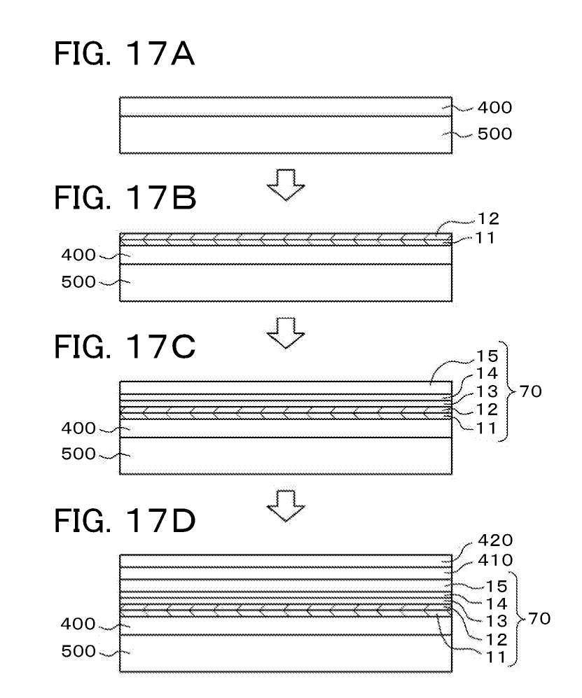

The reason that, in FIG. 16, the third barrier layer 70 is formed on the second polyimide substrate 400 is to block the moisture infiltration from the side of the second polyimide substrate 400. FIGS. 17A to 17B are diagrams illustrating how to form the third barrier layer 70. In a process, FIG. 17A, the polyimide substrate 400 is formed on a glass substrate 500, which is a mother substrate. Thereafter, as illustrated in a process FIG. 17B, the undercoat layer 11 made of metal such as Al is formed on the second polyimide substrate 400. Formed on the undercoat layer 11 is the AlOx layer 12, which is 30 to 80 nm thick. The undercoat layer 11 made of metal is formed thin because it needs to allow the passage of light.

Thereafter, as illustrated in a process FIG. 17C, an SiO/SiN/SiO layer is formed on the AlOx layer 12 to complete the third barrier layer 70. As illustrated in a process FIG. 17D, the color filter 410 and the overcoat film 420 are then formed on the third barrier layer 70 in the stated order.

The resultant counter mother substrate is glued with the adhesive 50 to the other mother substrate on which the organic EL layers and so forth have been formed. The glued mother substrates are then separated into individual organic EL cells.

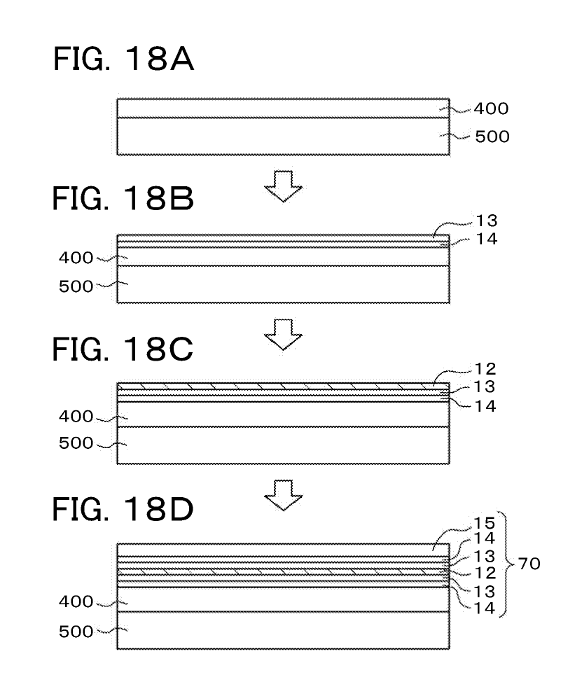

FIGS. 18A to 18D are diagrams illustrating the structure of the third barrier layer 70 and its fabricating process according to another example of Embodiment 5. FIG. 18A to 18D differ from FIG. 17A to 17D in that, in the former, the undercoat layer is not formed of a metal but of SiN and SiO. If the reduced transmittance resulting from the metal-made undercoat layer poses a problem, an SiN film, an SiO film, or a laminated layer of an SiN/SiO layer can instead be used as the undercoat layer 11.

In a process FIG. 18A, the polyimide substrate 400 is formed on the glass substrate 500. In a process FIG. 18B, the SiN layer 14 and the SiO layer 13 are formed on the polyimide substrate 400. In a process FIG. 18C, the AlOx layer 12, which is 30 to 80 nm thick, is formed as the barrier layer. In a process FIG. 18D, a laminated layer of an SiO/SiN/SiO layer is formed. Thereafter, the glass substrate 500 is removed from the second polyimide substrate 400 by laser abrasion or the like and replaced by the second protective film 2 to be glued to the second polyimide substrate 400.

In the above case as well, in which the organic EL display device uses a white-light-emitting organic EL layer and a color filter, an AlOx film having a high moisture blocking effect can be formed on the side of the color filter, which makes the organic EL display device highly reliable.

What is claimed is:

1. An organic EL display device comprising:
an organic EL layer as a light-emitting layer formed on a resin substrate; and
a barrier layer formed between the organic EL layer and the resin substrate, the barrier layer including an undercoat layer and an AlOx layer,
wherein the undercoat layer is formed closer to the resin substrate than the AlOx layer.

2. The organic EL display device of claim 1, wherein the resin substrate is formed of a polyimide.

3. The organic EL display device of claim 1, wherein the undercoat layer is formed of a metal.

4. The organic EL display device of claim 1, wherein the undercoat layer is formed of Al.

5. The organic EL display device of claim 1, wherein the undercoat layer is an SiO layer, an SiN layer, or a laminated layer of an SiO film and an SiN film.

6. The organic EL display device of claim 1, wherein the barrier layer further includes one of an SiO layer and an SiN layer, or a laminated layer of an SiO film and an SiN film.

7. The organic EL display device of claim 1, wherein
a protective film is disposed while covering the organic EL layer;
a second barrier layer including a second undercoat layer and a second AlOx layer is formed between the protective film and the organic EL layer,
the second undercoat layer is formed closer to the protective film than the second AlOx layer.

8. The organic EL display device of claim 7, wherein the second undercoat layer is formed of Al.

9. The organic EL display device of claim 7, wherein the second undercoat layer is one of an SiO layer and an SiN layer, or a laminated layer of an SiO film and an SiN film.

10. The organic EL display device of claim 7, wherein the second barrier layer further includes one of an SiO layer and an SiN layer, or a laminated layer of an SiO film and an SiN film.

11. The organic EL display device of claim 7, wherein a color filter is formed between the second barrier layer and the organic EL layer.

12. The organic EL display device of claim 7, wherein a polyimide substrate is formed between the protective film and the organic EL layer, and the second barrier layer is formed on the polyimide substrate.

13. An organic EL display device comprising:
an organic EL layer as a white-light-emitting layer formed on a first resin substrate;
a first barrier layer formed on the first resin substrate, the first barrier layer including a first undercoat layer and a first AlOx layer, the first undercoat layer being formed closer to the first resin substrate than the first AlOx layer;
a second resin substrate covering the organic EL layer;
a second barrier layer formed between the second resin substrate and the organic EL layer, the second barrier layer including a second undercoat layer and a second AlOx layer, the second undercoat layer being formed closer to the second resin substrate than the second AlOx layer; and
a color filter formed between the second barrier layer and the organic EL layer.

14. The organic EL display device of claim 13, wherein the first and second resin substrates are formed of a polyimide.

15. The organic EL display device of claim 13, wherein the first undercoat layer or the second undercoat layer is formed of Al.

16. The organic EL display device of claim 13, wherein the first undercoat layer or the second undercoat layer is one of an SiO layer and an SiN layer, or a laminated layer of an SiO film and an SiN film.

17. The organic EL display device of claim 13, wherein the first barrier layer or the second barrier layer further includes one of an SiO layer and an SiN layer, or a laminated layer of an SiO film and an SiN film.

18. An organic EL display device comprising:
an organic EL layer as a light-emitting layer formed on a resin substrate, the organic EL layer being sandwiched between an upper electrode and a lower electrode, the lower electrode not being in contact with a metal layer constituting a reflective film,
a barrier layer formed between the lower electrode and the resin substrate, the barrier layer including the metal layer and the AlOx layer, the metal layer being formed closer to the resin substrate than the AlOx layer, the metal layer constituting the reflective film.

19. The organic EL display device of claim 18, wherein the metal layer is formed of Al.

20. The organic EL display device of claim 18, wherein the barrier layer further includes one of an SiO layer and an SiN layer, or a laminated layer of an SiO film and an SiN film.
